(19) United States
(12) Patent Application Publication
(10) Pub. No.: US 2025/0221260 A1
(43) Pub. Date: Jul. 3, 2025

(54) DISPLAY DEVICE

(71) Applicant: LG Display Co., Ltd., Seoul (KR)

(72) Inventors: JoonYoung HEO, Paju-si (KR); Byungjin KIM, Paju-si (KR)

(21) Appl. No.: 18/910,941

(22) Filed: Oct. 9, 2024

(30) Foreign Application Priority Data
Dec. 29, 2023 (KR) 10-2023-0197781

(51) Int. Cl. H10K 59/80

(52) U.S. Cl. CPC H10K 59/873

(57) ABSTRACT

A display device includes a base substrate including a display area and a non-display area; a planarization layer formed over the base substrate, and including at least one trench which is formed to be recessed in a part corresponding to the non-display area; a first electrode disposed in a part corresponding to the display area on the planarization layer; a bank layer disposed on the planarization layer and formed with an opening which exposes the first electrode; a light emitting layer disposed in parts corresponding to the display area and the non-display area, and covering portions of the first electrode, the bank layer and the planarization layer; and an encapsulating layer covering the light emitting layer, wherein the light emitting layer disposed in the trench is formed only on the bottom surface of the trench to be disconnected.

### CROSS-REFERENCE TO RELATED APPLICATION

This application claims priority from Korean Patent Application No. 10-2023-0197781 filed on Dec. 29, 2023, which is hereby incorporated by reference for all purposes as if fully set forth herein.

### BACKGROUND

### Technical Field

Embodiments of the present disclosure relate to a display device.

### Description of Related Art

As the information age is entered, the field of displays which visually express electrical information signals has developed rapidly, and in response to this, various display devices with excellent performance such as thinness, light weight and low power consumption are being developed.

Specific examples of such display devices include a liquid crystal display device (LCD), a plasma display panel device (PDP), a field emission display device (FED), an organic light emitting display device (OLED), and so on.

### BRIEF SUMMARY

The inventors of the present disclosure have recognized the benefit of providing a larger display area in a display device by narrowing the bezel (e.g., reducing or minimizing the edge part where no image is displayed and increasing the area where an image is output, thereby offering a wider and larger image to users). In general, a display device may include, in order to protect a light emitting element from external moisture and oxygen, an encapsulation layer made of an organic material and a protective layer made of an inorganic material. Previously, both the encapsulation layer and the protective layer cover both the top and the side of the light emitting element to improve moisture penetration resistance, but recently, in order to implement a narrow bezel, the encapsulation layer is formed to cover only the top of the light emitting element. That is to say, as the encapsulation layer which is made of an organic material and is thus relatively thick covers only the top of the light emitting element and the protective layer which is made of an inorganic material thinner than an organic material covers the top and the side of the light emitting element, a narrow bezel is implemented.

However, although such a structure may implement a narrow bezel, a problem arises in that, since it is difficult to effectively block moisture introduced through the side of a bezel area, moisture penetration resistance deteriorates. Accordingly, when moisture is introduced through the side of the bezel area, a problem arises in that introduced moisture flows into the end of the light emitting element and thus the reliability of a display device deteriorates.

Accordingly, the inventors of the present disclosure have provided various embodiments of a display device capable of solving reliability deterioration due to moisture penetration, by disconnecting a light emitting element located in a bezel area and thereby blocking a path through which moisture flows.

Embodiments of the present disclosure are directed to providing a display device capable of securing the reliability of the display device, by forming a trench in a bezel area of a planarization layer and forming a light emitting element to be disconnected in the trench so as to block a path through which moisture flows.

Embodiments of the present disclosure are directed to providing a display device with excellent moisture penetration resistance, by increasing a moisture penetration path by the length of a light emitting element located in a trench.

Embodiments of the present disclosure are directed to providing a display device capable of implementing a narrow bezel and having a lightweight, by forming an encapsulation layer made of an organic material to cover only the top of a light emitting element.

According to an embodiment of the present disclosure, a display device may include: a base substrate including a display area and a non-display area which surrounds the display area; a planarization layer formed over the base substrate, and including at least one trench which is formed to be recessed in a part corresponding to the non-display area; a plurality of first electrodes disposed on the planarization layer; a bank layer covering ends of the first electrodes which are disposed in the display area; a light emitting layer disposed in parts corresponding to the display area and the non-display area, and disconnected in the non-display area; and an encapsulation layer covering the light emitting layer.

According to an embodiment of the present disclosure, a display device may include: a base substrate including a display area and a non-display area which surrounds the display area; a planarization layer formed over a base substrate, and including a plurality of trenches which are formed to be recessed in a part corresponding to the non-display area and at least one protruding member which is disposed between the trenches; a plurality of first electrodes disposed on the planarization layer; a bank layer covering ends of the first electrodes which are disposed in the display area; a light emitting layer disposed in parts corresponding to the display area and the non-display area, and disconnected in the non-display area; and an encapsulation layer covering the light emitting layer in parts corresponding to the display area and the non-display area.

According to the embodiments of the present disclosure, it is possible to provide a display device capable of securing the reliability of the display device, by forming a trench in a bezel area of a planarization layer and forming a light emitting element to be disconnected in the trench so as to block a path through which moisture flows.

According to the embodiments of the present disclosure, it is possible to provide a display device with excellent moisture penetration resistance, by increasing a moisture penetration path by the length of a light emitting element located in a trench.

According to the embodiments of the present disclosure, it is possible to provide a display device capable of implementing a narrow bezel and having a lightweight, by forming an encapsulation layer made of an organic material to cover only the top of a light emitting element.

### BRIEF DESCRIPTION OF THE SEVERAL VIEWS OF THE DRAWINGS

FIG. 1 is a system configuration diagram of a display device according to an embodiment of the present disclosure.

FIG. 2 is a cross-sectional view of the display device shown in FIG. 1, taken along the line A-A′.

FIGS. 3A to 3G are views illustrating a process sequence for manufacturing the display device illustrated in FIG. 2.

FIG. 4 is a cross-sectional view of a display device according to another embodiment of the present disclosure.

FIGS. 5A to 5D are views illustrating a process sequence for manufacturing the display device illustrated in FIG. 4.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms, such as “first,” “second,” “A,” “B,” “(A),” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for elements or features, or corresponding information (e.g., level, range, etc.) include a tolerance or error range (e.g., 5%) that may be caused by various factors (e.g., process factors, internal or external impact, noise, etc.) even when a relevant description is not specified. Further, the term “may” fully encompasses all the meanings of the term “can.”

Hereinafter, various embodiments of the present disclosure will be described in detail with reference to accompanying drawings.

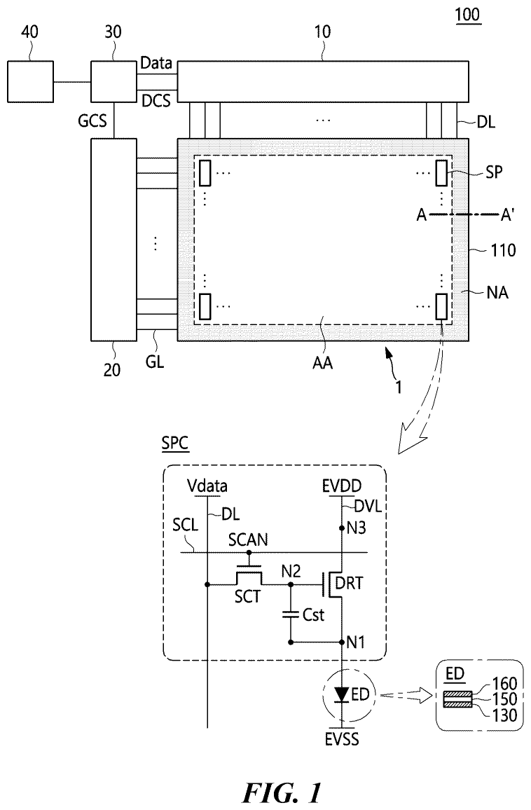

FIG. 1 is a system configuration diagram of a display device according to an embodiment of the present disclosure.

Referring to FIG. 1, the display driving system of a display device 100 according to the embodiment of the present disclosure may include a display panel 1 and a display driving circuit for driving the display panel 1.

The display panel 1 may include a display area AA in which an image is displayed and a non-display area NA in which an image is not displayed. The display panel 1 may include a plurality of subpixels SP which are disposed on a base substrate 110 to display an image.

The display panel 1 may include a plurality of signal wirings which are disposed on the base substrate 110. For example, the plurality of signal wirings may include data lines DL, gate lines GL, driving voltage lines, etc.

Each of the plurality of data lines DL may be disposed to extend in a first direction (e.g., a column direction or a row direction), and each of the plurality of gate lines GL may be disposed to extend in a direction intersecting the first direction.

The display driving circuit may include a data driving circuit 10 and a gate driving circuit 20, and may further include a controller 30 for controlling the data driving circuit 10 and the gate driving circuit 20.

The data driving circuit 10 may output data signals (also referred to as data voltages) corresponding to an image signal to the plurality of data lines DL. The gate driving circuit 20 may generate gate signals and output the gate signals to the plurality of gate lines GL. The controller 30 may convert input image data inputted from an external host 40 to suit a data signal format employed in the data driving circuit 10, and may supply converted image data to the data driving circuit 10.

The data driving circuit 10 may include at least one source driver integrated circuit. For example, each source driver integrated circuit may be connected to the display panel 1 in a tape automated bonding (TAB) method, may be connected to the bonding pads of the display panel 1 in a chip-on-glass (COG) or chip-on-panel (COP) method, or may be connected to the display panel 1 by being implemented in a chip-on-film (COF) method.

The gate driving circuit 20 may be connected to the display panel 1 in a tape automated bonding (TAB) method, may be connected to the bonding pads of the display panel 1 in a COG or COP method, may be connected to the display panel 1 according to a COF method, or may be formed in the non-display area NA of the display panel 1 in a gate-in-panel (GIP) type.

Referring to FIG. 1, in the display device 100 according to the embodiment of the present disclosure, each subpixel SP may include a light emitting element ED and a pixel driving circuit SPC for driving the light emitting element ED. The pixel driving circuit SPC may include a driving transistor DRT, a scan transistor SCT and a storage capacitor Cst.

The driving transistor DRT may drive the light emitting element ED by controlling current flowing to the light emitting element ED. The scan transistor SCT may transfer a data voltage Vdata to a second node N2, which is the gate node of the driving transistor DRT. The storage capacitor Cst may be configured to maintain a voltage for a predetermined period of time.

The light emitting element ED may include a first electrode 130, a second electrode 160, and a light emitting layer 150 located between the first electrode 130 and the second electrode 160. The first electrode 130 may be a pixel electrode which is involved in the formation of the light emitting element ED of each subpixel SP, and may be electrically connected to a first node N1 of the driving transistor DRT. The second electrode 160 may be a common electrode which is involved in the formation of light emitting elements ED of all subpixels SP, and may be applied with a base voltage EVSS.

For example, the light emitting element ED may be an organic light emitting diode (OLED), an inorganic-based light emitting diode (LED) or a quantum dot light emitting element which is a semiconductor crystal that emits light on its own.

The driving transistor DRT as a transistor for driving the light emitting element ED may include the first node N1, the second node N2 and a third node N3. The first node N1 may be a source or drain node, and may be electrically connected to the first electrode 130 of the light emitting element ED. The second node N2 may be the gate node, and may be electrically connected to a source or drain node of the scan transistor SCT. The third node N3 may be a drain or source node, and may be electrically connected to a driving voltage line DVL which supplies a driving voltage EVDD. Hereinbelow, for the sake of convenience in explanation, it may be described as an example that the first node N1 is a source node and the third node N3 is a drain node.

The scan transistor SCT may switch the connection between a data line DL and the second node N2 of the driving transistor DRT. In response to a scan signal SCAN supplied from a scan line SCL as a type of gate line GL, the scan transistor SCT may control the connection between the second node N2 of the driving transistor DRT and a corresponding data line DL among the plurality of data lines DL.

The storage capacitor Cst may be configured between the first node N1 and the second node N2 of the driving transistor DRT.

The structure of the subpixel SP shown in FIG. 1 is nothing but a mere example for explanation, and may further include at least one transistor or at least one capacitor. Each of the plurality of subpixels SP may have the same structure, or some of the plurality of subpixels SP may have a different structure. Each of the driving transistor DRT and the scan transistor SCT may be an n-type transistor or a p-type transistor.

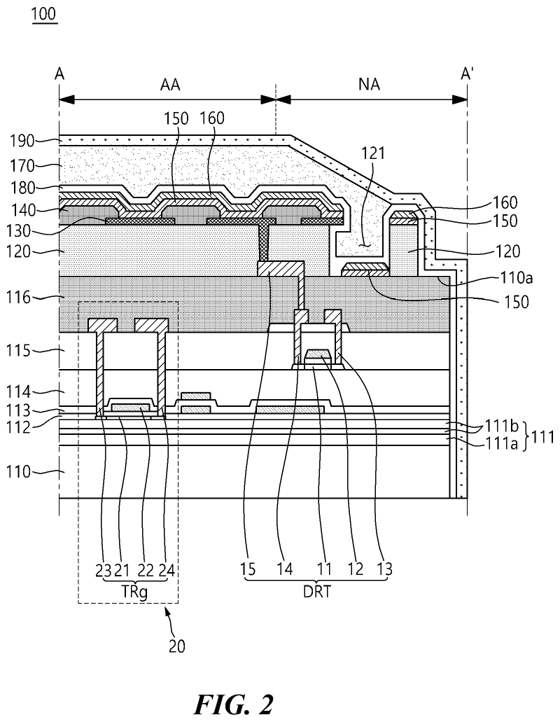

FIG. 2 is a cross-sectional view of the display device shown in FIG. 1, taken along the line A-A′.

Referring to FIG. 2, the display device 100 may include the base substrate 110, a planarization layer 120, the first electrode 130, a bank layer 140, the light emitting layer 150, the second electrode 160 and an encapsulation layer 170.

The base substrate 110 is to support various components of the display device 100, and may include the display area AA which displays an image by the plurality of subpixels SP and the non-display area NA which surrounds the display area AA. For example, the base substrate 110 may be formed of an insulating material such as a glass substrate or a plastic substrate. The non-display area NA may be formed at an edge part, and the display area AA may be formed inside the edge part.

The base substrate 110 may be composed of at least two layers, and a transistor, a GIP circuit, a wiring, etc., may be disposed over the base substrate 110. For example, a first buffer layer 111, a first interlayer insulating layer 112, a gate insulating layer 113, a second buffer layer 114, a second interlayer insulating layer 115 and a planarization layer 116 may be sequentially stacked on the base substrate 110.

The first buffer layer 111 may be a single layer or a multilayer. When the first buffer layer 111 is a multilayer, the first buffer layer 111 may include a multi-buffer layer 111a and two active buffer layers 111b.

A GIP circuit 20 formed over the base substrate 110 may include a GIP type gate driving circuit TRg. In other words, the GIP circuit 20 may be one of transistors included in the GIP type gate driving circuit TRg, and may be made of, for example, low temperature polysilicon (LTPS). In the present embodiment, the GIP circuit 20 may be formed at each of both side parts of the display panel 1.

Referring to FIG. 2, the GIP circuit 20 disposed at each of both side parts of the display panel 1 is illustrated as being located in the display area AA as the inner part of the display panel 1. More specifically, the GIP circuit 20 is illustrated as being located below the first electrode 130. However, if necessary, the GIP circuit 20 may be located in the non-display area NA, and may be located below the planarization layer 120 on which the light emitting layer 150 and the second electrode 160 are stacked.

The gate driving circuit TRg may be disposed on the active buffer layer 111b, and may include an active layer 21, a gate electrode 22, a source electrode 23 and a drain electrode 24. The active layer 21 may include a channel area where a channel is formed, a source connection area on one side of the channel area, and a drain connection area on the other side of the channel area. The source electrode 23 and the drain electrode 24 may be connected to the source connection area and the drain connection area, respectively, of the active layer 21 through holes formed in the second interlayer insulating layer 115, the second buffer layer 114, the gate insulating layer 113 and the first interlayer insulating layer 112.

The planarization layer 120 is formed over the base substrate 110 to planarize the top of the base substrate 110, and may be an organic layer. For example, the planarization layer 120 may be formed of an organic material such as acrylic resin, epoxy resin, phenolic resin, polyamide resin and polyimide resin.

The planarization layer 120 may include at least one trench 121 which is formed to be recessed in a part corresponding to the non-display area NA. For example, when the base substrate 110 is formed in a quadrangular plate shape, the trench 121 may be formed to be recessed in four edge parts of the non-display area NA. The trench 121 may be formed in a closed loop shape as each edge part is formed in a straight line shape and both ends of the four edge parts are connected to each other. The shape of the trench 121 is not limited thereto, and both ends of the edge parts may not be connected to each other but be separated from each other.

A plurality of first electrodes 130 may be disposed on the planarization layer 120. For example, the first electrodes 130 may be disposed in the display area AA and the non-display area NA, and the first electrodes 130 disposed in the non-display area NA may be formed to have a structure which surrounds the display area AA. The first electrode 130 disposed in the display area AA may be electrically connected to the driving transistor DRT which is formed over the base substrate 110.

The first electrode 130 may be made of a transparent metallic oxide material such as indium tin oxide (ITO) or indium zinc oxide (IZO) with good conductivity. Besides, the first electrode 130 may be made of a metal material such as magnesium (Mg), calcium (Ca), sodium (Na), titanium (Ti), indium (In), yttrium (Y), lithium (Li), gadolinium (Gd), aluminum (Al), silver (Ag), tin (Sn) or lead (Pb).

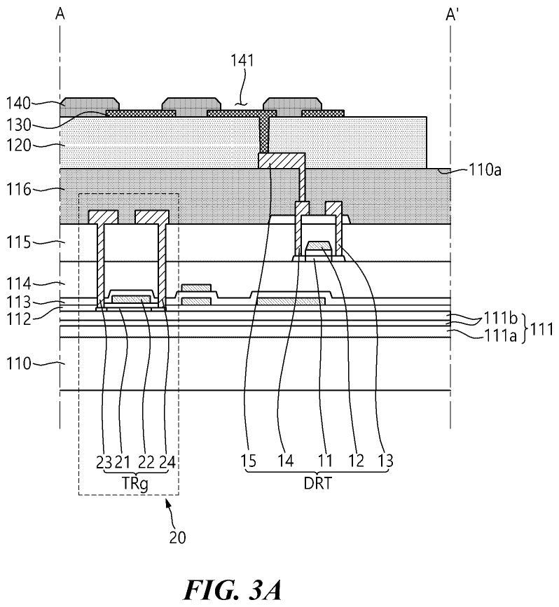

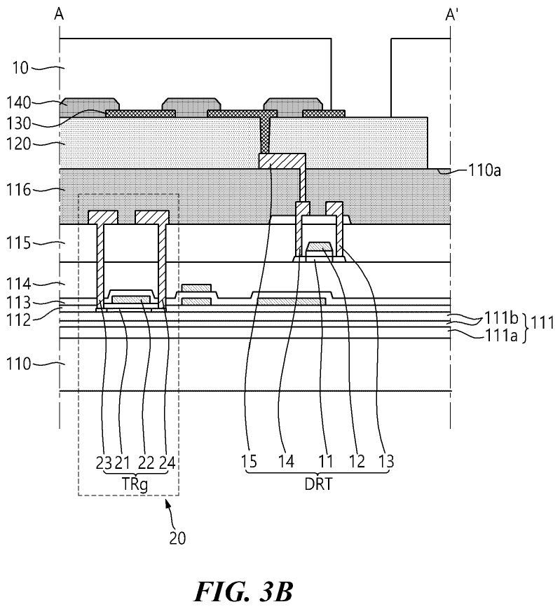

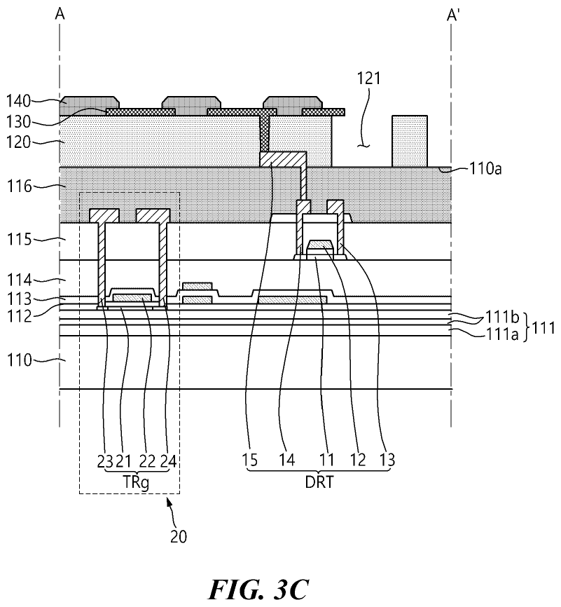

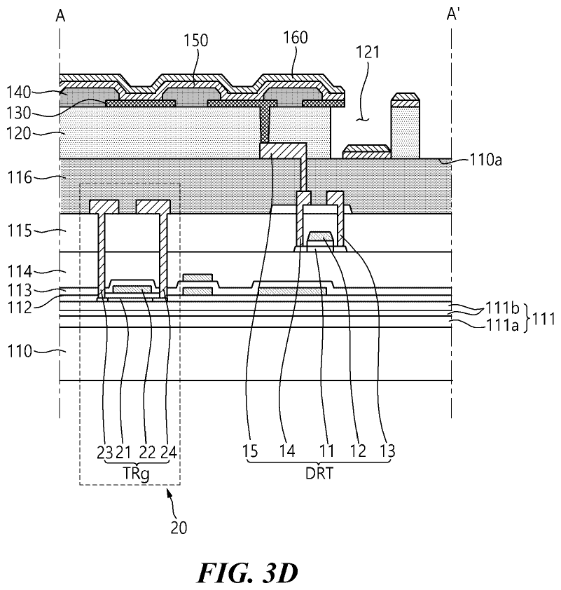

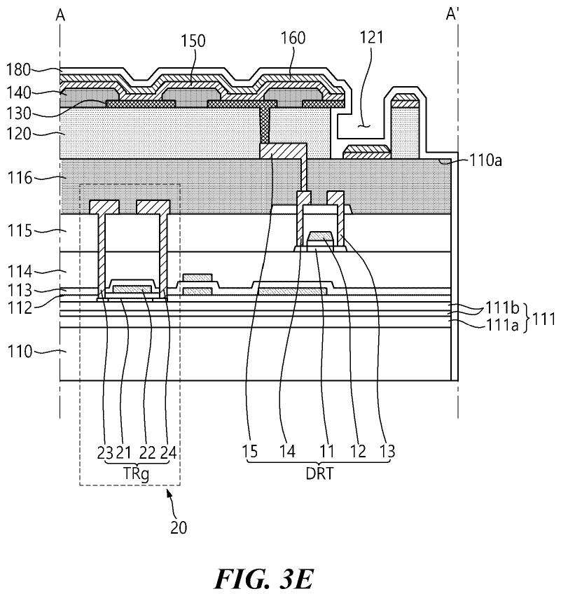

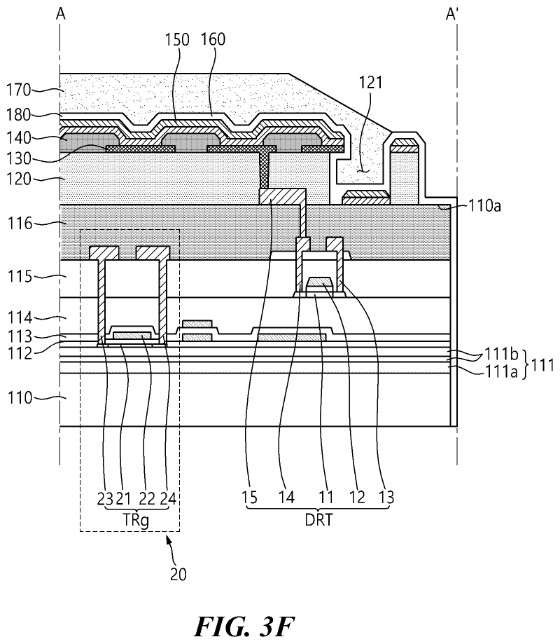

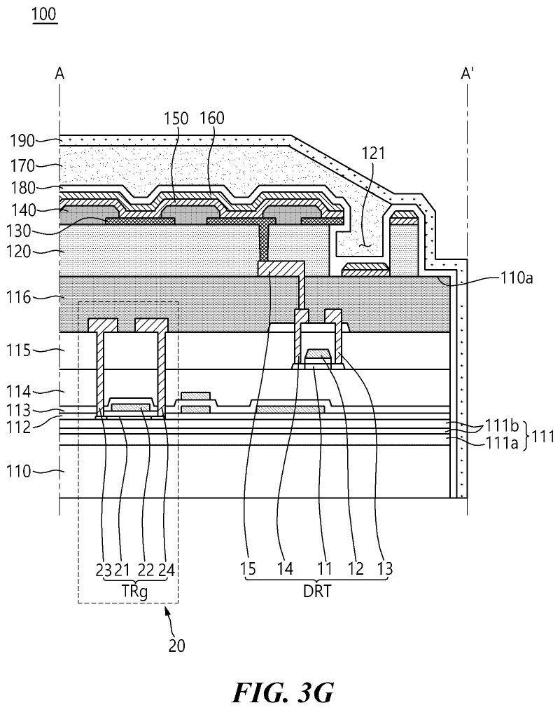

The bank layer 150 may cover the end of the first electrode 130 disposed in the display area AA. For example, the bank layer 140 may be disposed on the planarization layer 120, and may be formed with an opening 141 (see FIG. 3A) which exposes the first electrode 130. Namely, the bank layer 150 is to partition a pixel, and light may be outputted through the opening 141 formed in the bank layer 140.

The light emitting layer 150 may be disposed in parts corresponding to the display area AA and the non-display area NA, and may be disconnected in the non-display area NA. For example, the light emitting layer 150 may include a hole transport layer, an organic light emitting layer and an electron transport layer. In this case, when voltages are applied to the first electrode 130 and the second electrode 160, holes and electrons may move to the organic light emitting layer through the hole transport layer and the electron transport layer, respectively, and may combine with each other in the organic light emitting layer to emit light.

The second electrode 160 may be disposed on the light emitting layer 150. The second electrode 160 may be disconnected in the non-display area NA like the light emitting layer 150. For example, the second electrode 160 may be a common electrode which is involved in the formation of light emitting elements ED of all subpixels SP, and may be applied with the base voltage EVSS.

In the present embodiment, the first electrode 130 may be an anode which supplies holes to the light emitting layer 150, and the second electrode 160 may be a cathode which supplies electrons to the light emitting layer 150. However, the embodiment is not limited thereto, and the first electrode 130 and the second electrode 160 may be changed in their roles.

The encapsulation layer 170 is to prevent moisture and foreign substances from penetrating into the light emitting element ED, and may cover the light emitting layer 150 or the second electrode 160. For example, the encapsulation layer 170 may be formed of an organic insulating material such as acrylic resin, epoxy resin, polyimide, polyethylene and silicon oxycarbon (SiOC).

In the present embodiment, the encapsulation layer 170 is illustrated as being composed of a single layer made of an organic material, but may also be composed of a multilayer in which an inorganic material and an organic material are alternately disposed.

The distal end portion of the encapsulation layer 170 may be disposed in the trench 121. More specifically, the distal end of the encapsulation layer 170 which extends from the display area AA and is disposed in the non-display area NA may be blocked by the planarization layer 120 which is located outermost. Hence, it is possible to prevent the encapsulation layer 170 from being exposed to the outside of the display device 100 or from invading a pad electrode. In addition, since there is no need to separately install, around the encapsulation layer 170, a dam for blocking the flow of an organic material included in the encapsulation layer 170, a process may be simplified and at the same time a narrow bezel may be implemented.

According to the present embodiment, the light emitting layer 150 which is disposed in the trench 121 may be formed only on the bottom surface of the trench 121, and thereby, may be disconnected. In this way, as the end of the light emitting layer 150 is disconnected in the trench 121, moisture introduced from the outside may be blocked from flowing inward through the end of the light emitting layer 150. That is to say, a path through which moisture flows may be blocked through the disconnected portion of the light emitting layer 150.

In addition, since a moisture penetration path is lengthened by the height of the inner wall of the trench 121, even when moisture is introduced from the outside, a progress time may be slowed down. The larger the height of the trench 121 formed in the encapsulation layer 120 is, the longer the moisture penetration path may be. Therefore, it is desirable to form the trench 121 to have a maximum height. In other words, when the trench 121 is formed in a hole shape with no residual layer on the bottom of the trench 121, the moisture penetration path may be formed to have a maximum height. However, when forming the trench 121 in a hole shape, underlying components may be damaged during processing. Therefore, the trench 121 may be formed in a groove shape so that a residual layer of a thinnest possible thickness may be left on the bottom of the trench 121.

In this way, by, through the trench 121, increasing a moisture penetration path for moisture to be introduced into the light emitting layer 150 and at the same time blocking a path through which moisture flows, the lifespan of the display device 100 may be increased and reliability deterioration due to moisture penetration may be solved.

According to the present embodiment, like the light emitting layer 150, the second electrode 160 may be disposed in parts corresponding to the display area AA and the non-display area NA, and may be disconnected in the trench 121 of the non-display area NA. Accordingly, even when moisture is introduced into the end of the second electrode 160 which is disposed in the non-display area NA, a path through which moisture flows is blocked, whereby the reliability of the display device 100 may be secured.

The display device 100 according to the present embodiment may further include a first protective layer 180 and a second protective layer 190.

The first protective layer 180 is to protect the underlying light emitting element ED from external moisture, oxygen, impact, etc., and may cover the top of the light emitting element ED, the inner wall of the trench 121 and the outer side surface of the planarization layer 120. For example, when the first electrode 130 is located uppermost in the light emitting element ED, the first protective layer 180 may cover the top of the first electrode 130, the inner wall of the trench 121 and the outer side surface of the planarization layer 120, and when the second electrode 160 is located uppermost in the light emitting element ED, the first protective layer 180 may cover the top of the second electrode 160, the inner wall of the trench 121 and the outer side surface of the planarization layer 120.

The first protective layer 180 may be formed of an inorganic insulating material capable of low temperature deposition, such as silicon nitride (SiNx), silicon oxide (SiOx), silicon oxynitride (SiON) or aluminum oxide (Al2O3). In this way, when the first protective layer 180 is deposited in a low-temperature atmosphere, the first protective layer 180 may prevent the light emitting layer 150 including an organic material vulnerable to a high-temperature atmosphere from being damaged during a deposition process.

The second protective layer 190 may cover the encapsulation layer 170 and a portion of the first protective layer 180 to prevent, together with the encapsulation layer 170 and the first protective layer 180, moisture and oxygen from being introduced into the light emitting element ED. Specifically, the width of the base substrate 110 may be formed to be larger than the width of the planarization layer 120, so that a protrusion 110a is formed at the outer part of the base substrate 110, and the second protective layer 190 may further cover the top of the protrusion 110a.

Namely, the second protective layer 190 may be formed to cover the encapsulation layer 170, the first protective layer 180 and the protrusion 110a of the base substrate 110, thereby improving the sealing efficiency to effectively block moisture and oxygen introduced toward the light emitting element ED.

FIGS. 3A to 3G are views illustrating a process sequence for manufacturing the display device illustrated in FIG. 2. A process of manufacturing the display device 100 of FIG. 2 will be schematically described below with reference to FIGS. 3A to 3G.

Referring to FIG. 3A, after preparing a base substrate 110, a planarization layer 120 may be formed over the base substrate 110. The planarization layer 120 may be formed to be smaller than the base substrate 110, and thus, a protrusion 110a may be formed at the end of the base substrate 110.

A first electrode 130 and a bank layer 140 may be sequentially stacked on the planarization layer 120. The first electrode 130 may be a pixel electrode which is involved in the formation of the light emitting element ED of each subpixel SP, and may be disposed in the display area AA and a part of the non-display area NA.

Thereafter, as shown in FIG. 3B, a photoresist pattern layer 10 which is formed with an opening pattern to expose a portion of the distal end of the first electrode 130 and a portion of the planarization layer 120 is disposed, and a photolithography process and an etching process may be performed. The etching process may be performed as dry etching or wet etching, and may use a solution that selectively etches only the planarization layer 120.

As shown in FIG. 3C, a trench 121 is formed on the planarization layer 120 to have the same pattern as the opening pattern of the photoresist pattern layer 10. When the trench 121 is formed on the planarization layer 120 in this way, the photoresist pattern layer 10 is removed.

As shown in FIG. 3D, deposition processes of a light emitting layer 150 and a second electrode 160 may be performed. When the deposition processes are performed using a photomask in which an opening of the same pattern as the trench 121 is formed, the light emitting layer 150 and the second electrode 160 are not deposited on the inner wall of the trench 121. That is to say, since the light emitting layer 150 and the second electrode 160 are deposited only on the bottom surface of the trench 121, the light emitting layer 150 and the second electrode 160 may be disconnected in the trench 121.

In this state, as shown in FIG. 3E, a deposition process of a first protective layer 180 may be performed. When the deposition process is completed, the first protective layer 180 may cover the top of the second electrode 160, the inner wall of the trench 121 and the outer side surface of the planarization layer 120.

After the deposition process of the first protective layer 180, as shown in FIG. 3F, an encapsulation layer 170 may be formed using a method such as an inkjet coating or slit coating process. The encapsulation layer 170 may cover the entire first protective layer 180 disposed in the display area AA, but in the non-display area NA, may cover only the first protective layer 180 which is disposed in the trench 121.

After the encapsulation layer 170 is formed in this way, as shown in FIG. 3G, a deposition process of a second protective layer 190 may be performed. The second protective layer 190 may cover the encapsulation layer 170, the first protective layer 180 and the protrusion 110a of the base substrate 110.

In this way, when the respective processes are completed, a display device 100 in which the light emitting layer 150 and the second electrode 160 are disconnected in the trench 121 of the non-display area NA may be implemented. Accordingly, even when moisture is introduced into the non-display area NA which forms a bezel, a path through which moisture flows through the light emitting layer 150 and the second electrode 160 is blocked, whereby it is possible to secure the reliability of the display device 100.

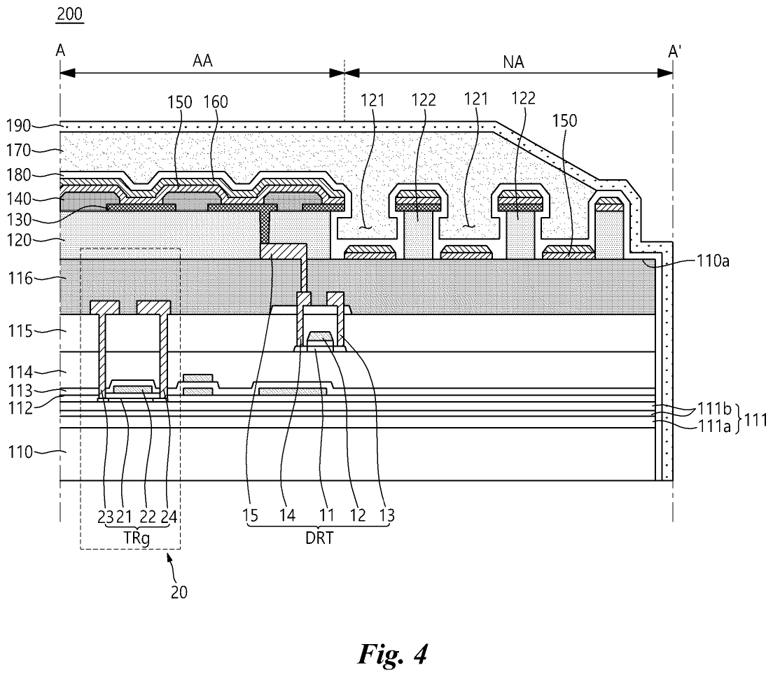

FIG. 4 is a cross-sectional view of a display device according to another embodiment of the present disclosure. In the present embodiment, description will be made mainly on differences from the embodiment described above.

Referring to FIG. 4, a display device 200 may include a base substrate 110, a planarization layer 120, a first electrode 130, a bank layer 140, a light emitting layer 150, a second electrode 160 and an encapsulation layer 170.

The base substrate 110 may include a display area AA and a non-display area NA which surrounds the display area AA.

The planarization layer 120 is formed over the base substrate 110 to planarize the top of the base substrate 110, and may include a trench 121 and a protruding member 122.

The trench 121 may be formed to be recessed in a part of the planarization layer 120 corresponding to the non-display area NA, and may be provided in a plural number. For example, two or more trenches 121 may be provided, and may be disposed between the display area AA and the non-display area NA to be spaced apart from each other. In other words, the trenches 121 may be disposed between the boundary between the display area AA and the non-display area NA and the non-display area NA.

The trenches 121 may be formed by etching the top of the planarization layer 120 in a predetermined pattern. By controlling a depth during the etching process, the trenches 121 may be formed into a groove shape with a residual layer on the bottom of each trench 121 or a hole shape with no residual layer on the bottom of each trench 121.

At least one protruding member 122 may be provided, and may be disposed between the trenches 121. In the drawing, it is illustrated that two protruding members 122 are disposed between three trenches 121 to be spaced apart from each other, but the numbers of trenches 121 and protruding members 122 are not limited thereto and may be increased or decreased.

The first electrode 130 is a pixel electrode which is involved in the formation of the light emitting element ED of each subpixel SP, and may be disposed in parts corresponding to the display area AA and the non-display area NA on the planarization layer 120. First electrodes 130 may not be formed in the entire non-display area NA but may be formed only in some portions of the non-display area NA. For example, the first electrode 130 may not be disposed in each of the trenches 121.

The bank layer 140 may be disposed on the planarization layer 120, and may cover the ends of the first electrodes 130 which are disposed in the display area AA.

The light emitting layer 150 may be disposed in parts corresponding to the display area AA and the non-display area NA, and may be disconnected in the non-display area NA. The light emitting layer 150 may cover portions of the first electrodes 130, the bank layer 140 and the planarization layer 120 in the display area AA and the non-display area NA. For example, the light emitting layer 150 formed in the non-display area NA may be disposed only on the bottom surfaces of the trenches 121, to be disconnected. Specifically, the light emitting layer 150 may be disposed on the bottom surfaces of the trenches 121 and the tops of the protruding members 122, respectively, and thereby, may be disconnected in the trenches 121. The width of the light emitting layer 150 disposed on the protruding member 122 may be formed to be larger than the width of the protruding member 122.

In this way, as the light emitting layer 150 is disconnected in the trenches 121, it is possible to block moisture introduced from the outside from flowing inward through the end of the light emitting layer 150. Namely, a path through which moisture flows may be blocked through the disconnected portion of the light emitting layer 150.

The light emitting layer 150 in the present embodiment may block more effectively a moisture penetration path because the number of disconnected portions is increased compared to the light emitting layer 150 of the display device 100 illustrated in FIG. 2 described above. That is to say, compared to FIG. 2, the number of disconnected areas is increased to lengthen a moisture penetration path, which may improve moisture penetration resistance and thus improve the reliability of the display device 200.

The second electrode 160 may be disposed on the top of the light emitting layer 150, and may be disconnected in the trenches 121. For example, the second electrode 160 may be disposed on the top of the light emitting layer 150 in the same pattern as the light emitting layer 150, and may be disconnected in the non-display area NA.

The encapsulation layer 170 is to prevent moisture and foreign substances from penetrating into the light emitting element ED, and may cover the light emitting layer 150 in parts corresponding to the display area AA and the non-display area NA. The distal end portion of the encapsulation layer 170 may be disposed in the trench 121.

The display device 200 according to the present embodiment may further include a first protective layer 180 and a second protective layer 190.

The first protective layer 180 may cover the top of the second electrode ED, the inner wall of the trench 121 and the outer side surface of the planarization layer 120. For example, when the first electrode 130 is located uppermost in the light emitting element ED, the first protective layer 180 may cover the top of the first electrode 130, the inner wall of the trench 121 and the outer side surface of the planarization layer 120, and when the second electrode 160 is located uppermost in the light emitting element ED, the first protective layer 180 may cover the top of the second electrode 160, the inner wall of the trench 121 and the outer side surface of the planarization layer 120.

The second protective layer 190 may cover the encapsulation layer 170 and a portion of the first protective layer 180 to prevent, together with the encapsulation layer 170 and the first protective layer 180, moisture and oxygen from being introduced into the light emitting element ED. Specifically, the width of the base substrate 110 may be formed to be larger than the width of the planarization layer 120, so that a protrusion 110a is formed at the outer part of the base substrate 110, and the second protective layer 190 may further cover the top of the protrusion 110a.

In this way, as the second protective layer 190 is formed to further cover the top of the protrusion 110a formed at the outer part of the base substrate 110, the sealing efficiency may be improved to effectively block moisture and oxygen introduced toward the light emitting element ED.

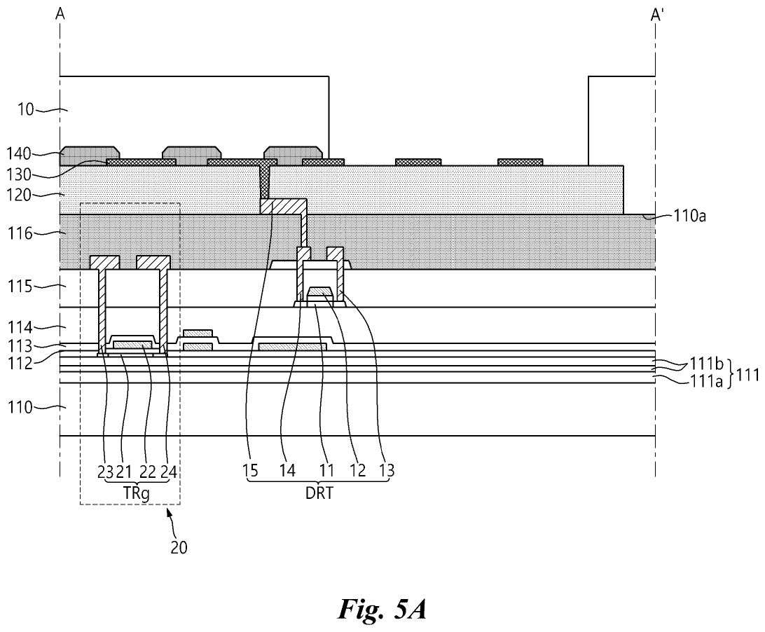

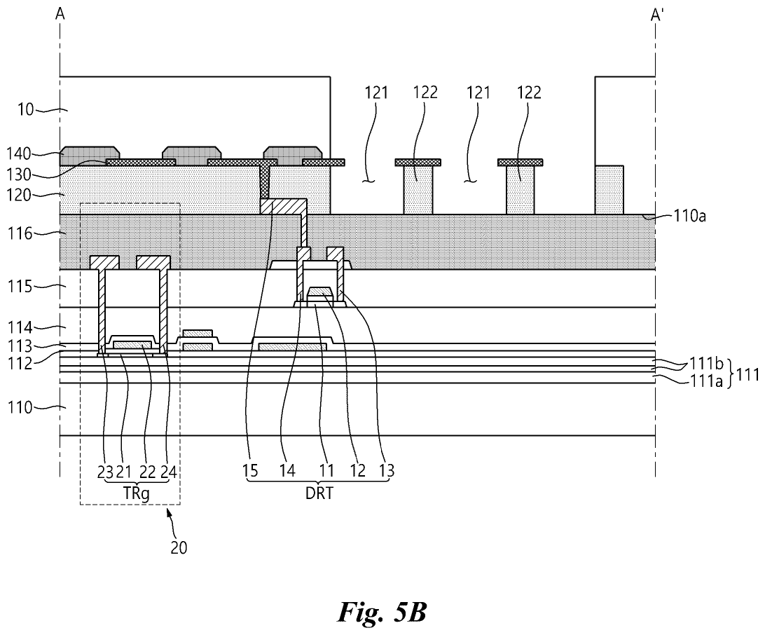

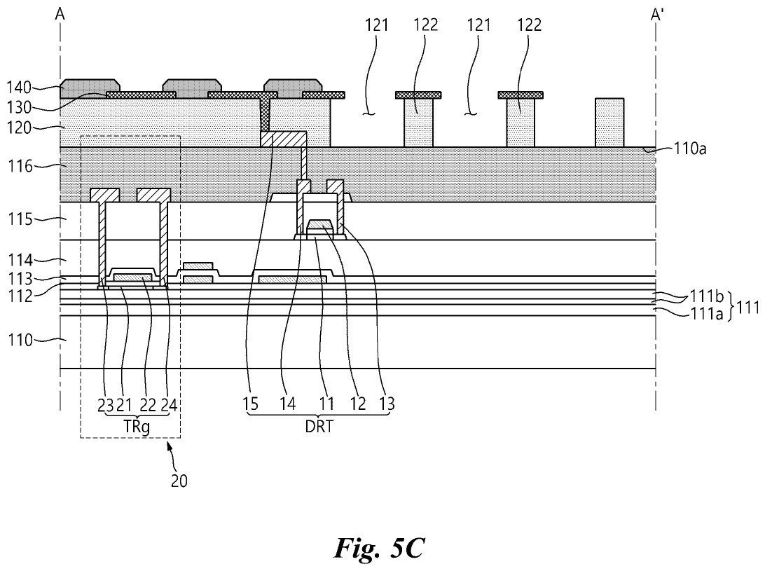

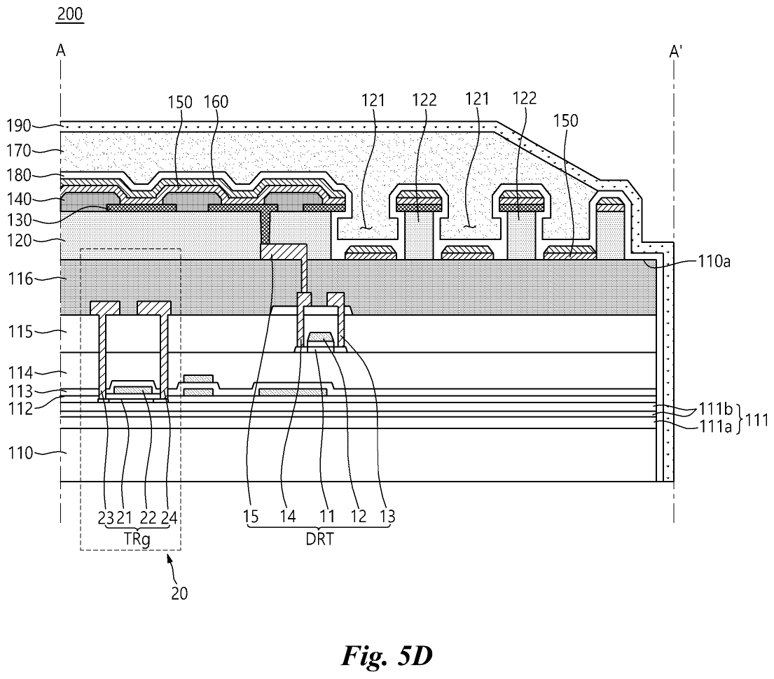

FIGS. 5A to 5D are views illustrating a process sequence for manufacturing the display device illustrated in FIG. 4. A process of manufacturing the display device 200 of FIG. 4 will be schematically described below with reference to FIGS. 5A to 5D.

Referring to FIG. 5A, after sequentially stacking a planarization layer 120, a first electrode 130 and a bank layer 140 over a base substrate 110, a photoresist pattern layer 10 formed with an opening pattern which exposes a portion of the first electrode 130 and a portion of the planarization layer 120 is disposed.

Thereafter, as shown in FIG. 5B, by performing a photolithography process and an etching process, a trench 121 which has the same pattern as the opening pattern is formed on the planarization layer 120. The etching process may be performed as dry etching or wet etching, and may use a solution that selectively etches only the planarization layer 120.

When the trench 121 is formed on the planarization layer 120 in this way, as shown in FIG. 5C, the photoresist pattern layer 10 is removed. Thereafter, as shown in FIG. 5D, when deposition processes of a light emitting layer 150, a second electrode 160, a first protective layer 180, an encapsulation layer 170 and a second protective layer 190 are sequentially performed, a display device 200 in which the light emitting layer 150 and the second electrode 160 are disconnected in the trench 121 of the non-display area NA may be implemented. Accordingly, even when moisture is introduced into the non-display area NA, a path through which moisture flows in the light emitting layer 150 and the second electrode 160 may be blocked, whereby the reliability of the display device 200 may be secured.

Brief description of the embodiments of the present disclosure described above is as follows.

According to embodiments of the present disclosure, a display device may include a base substrate including a display area and a non-display area which surrounds the display area; a planarization layer formed over the base substrate, and including at least one trench which is formed to be recessed in a part corresponding to the non-display area; a plurality of first electrodes disposed on the planarization layer; a bank layer covering ends of the first electrodes which are disposed in the display area; a light emitting layer disposed in parts corresponding to the display area and the non-display area, and disconnected in the non-display area; and an encapsulation layer covering the light emitting layer.

According to the embodiments of the present disclosure, the light emitting layer formed in the non-display area may be disposed only on a bottom surface of the trench, to be disconnected.

According to the embodiments of the present disclosure, the bank layer may be disposed on the planarization layer, and may be formed with openings which expose the first electrodes.

According to the embodiments of the present disclosure, the display device may further include a second electrode disposed on a top of the light emitting layer and disconnected in the trench.

According to the embodiments of the present disclosure, the trench may be formed in the shape of a groove with a residual layer on a bottom or a hole with no residual layer on a bottom.

According to the embodiments of the present disclosure, a distal end portion of the encapsulation layer may be disposed in the trench.

According to the embodiments of the present disclosure, the display device may further include a first protective layer covering a top of the first electrode, an inner wall of the trench and an outer side surface of the planarization layer.

According to the embodiments of the present disclosure, the display device may further include a second protective layer covering the encapsulation layer and a portion of the first protective layer.

According to the embodiments of the present disclosure, a width of the base substrate may be formed to be larger than a width of the planarization layer so that a protrusion is formed on an outer part of the base substrate, and the second protective layer may further cover a top of the protrusion.

According to embodiments of the present disclosure, a display device may include a base substrate including a display area and a non-display area which surrounds the display area; a planarization layer formed over a base substrate, and including a plurality of trenches which are formed to be recessed in a part corresponding to the non-display area and at least one protruding member which is disposed between the trenches; a plurality of first electrodes disposed on the planarization layer; a bank layer covering ends of the first electrodes which are disposed in the display area; a light emitting layer disposed in parts corresponding to the display area and the non-display area, and disconnected in the non-display area; and an encapsulation layer covering the light emitting layer in parts corresponding to the display area and the non-display area.

According to the embodiments of the present disclosure, the light emitting layer formed in each trench may be disposed only on a bottom surface of the trench, to be disconnected.

According to the embodiments of the present disclosure, the first electrode may not be disposed in each trench in the non-display area.

According to the embodiments of the present disclosure, the light emitting layer may be disposed on a bottom surface of each trench and a top of the protruding member in the non-display area, to be disconnected.

According to the embodiments of the present disclosure, the display device may further include a second electrode covering a top of the light emitting layer and disconnected in each trench.

According to the embodiments of the present disclosure, each trench may be formed in the shape of a groove with a residual layer on a bottom or a hole with no residual layer on a bottom.

According to the embodiments of the present disclosure, a width of the light emitting layer disposed on the protruding member may be formed to be larger than a width of the protruding member.

According to the embodiments of the present disclosure, a distal end portion of the encapsulation layer disposed in the non-display area may be disposed in each trench.

According to the embodiments of the present disclosure, the display device may further include a first protective layer covering a top of the first electrode, an inner wall of the trench and an outer side surface of the planarization layer.

According to the embodiments of the present disclosure, the display device may further include a second protective layer covering the encapsulation layer and a portion of the first protective layer.

According to the embodiments of the present disclosure, a width of the base substrate may be formed to be larger than a width of the planarization layer so that a protrusion is formed on an outer part of the base substrate, and the second protective layer may further cover a top of the protrusion.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. Other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a base substrate having thereon a display area and a non-display area adjacent to the display area;
a planarization layer on the base substrate, the planarization layer including at least one trench which is formed to be recessed in a part corresponding to the non-display area;
a plurality of first electrodes on the planarization layer;
a bank layer covering ends of the first electrodes which are disposed in the display area;
a light emitting layer disposed in parts corresponding to the display area and the non-display area, and disconnected in the non-display area; and
an encapsulation layer on the light emitting layer.

2. The display device of claim 1, wherein the light emitting layer formed in the non-display area is disposed only on a bottom surface of the trench, to be disconnected.

3. The display device of claim 1, wherein the bank layer is on the planarization layer, and is formed with openings which expose the first electrodes.

4. The display device of claim 1, further comprising:
a second electrode on a top of the light emitting layer, and disconnected in the trench.

5. The display device of claim 1, wherein the trench is formed in the shape of a groove with a residual layer on a bottom or a hole with no residual layer on a bottom.

6. The display device of claim 1, wherein a distal end portion of the encapsulation layer is disposed in the trench.

7. The display device of claim 1, further comprising:
a first protective layer covering a top of the first electrode, an inner wall of the trench, and an outer side surface of the planarization layer.

8. The display device of claim 7, further comprising:
a second protective layer covering the encapsulation layer and a portion of the first protective layer.

9. The display device of claim 8,
wherein a width of the base substrate is larger than a width of the planarization layer so that a protrusion is formed on an outer part of the base substrate, and
wherein the second protective layer further covers a top of the protrusion.

10. A display device, comprising:
a base substrate having thereon a display area and a non-display area adjacent to the display area;
a planarization layer on a base substrate, the planarization layer including a plurality of trenches which are formed to be recessed in a part corresponding to the non-display area and at least one protruding member which is disposed between the trenches;
a plurality of first electrodes on the planarization layer;
a bank layer covering ends of the first electrodes which are disposed in the display area;
a light emitting layer disposed in parts corresponding to the display area and the non-display area, and disconnected in the non-display area; and
an encapsulation layer on the light emitting layer in parts corresponding to the display area and the non-display area.

11. The display device of claim 10, wherein the light emitting layer formed in each trench is disposed only on a bottom surface of the trench, to be disconnected.

12. The display device of claim 10, wherein the first electrode is not disposed in each trench in the non-display area.

13. The display device of claim 10, wherein the light emitting layer is on a bottom surface of each trench and a top of the protruding member in the non-display area, to be disconnected.

14. The display device of claim 10, further comprising:
a second electrode covering a top of the light emitting layer, and disconnected in each trench.

15. The display device of claim 10, wherein each trench is formed in the shape of a groove with a residual layer on a bottom or a hole with no residual layer on a bottom.

16. The display device of claim 10, wherein a width of the light emitting layer on the protruding member is larger than a width of the protruding member.

17. The display device of claim 10, wherein a distal end portion of the encapsulation layer disposed in the non-display area is disposed in each trench.

18. The display device of claim 10, further comprising:
a first protective layer covering a top of the first electrode, an inner wall of the trench, and an outer side surface of the planarization layer.

19. The display device of claim 18, further comprising:
a second protective layer covering the encapsulation layer and a portion of the first protective layer.

20. The display device of claim 19,
wherein a width of the base substrate is larger than a width of the planarization layer so that a protrusion is formed on an outer part of the base substrate, and
wherein the second protective layer further covers a top of the protrusion.
